(19) United States
(12) Patent Application Publication
(10) Pub. No.: US 2023/0249604 A1
(43) Pub. Date: Aug. 10, 2023

(54) VEHICLE HEADLIGHT DEVICE

(71) Applicant: HONDA MOTOR CO., LTD., Tokyo (JP)

(72) Inventors: Masayoshi TAKORI, Saitama (JP); Yuji TSUCHIYA, Saitama (JP)

(21) Appl. No.: 18/163,885

(22) Filed: Feb. 3, 2023

(30) Foreign Application Priority Data
Feb. 9, 2022 (JP) 2022-018658

(51) Int. Cl. B60Q 1/04; B60W 30/09

(52) U.S. Cl. CPC B60Q 1/04; B60W 30/09; B60Q 2300/05; B60W 2554/4029

(57) ABSTRACT

Provided is a vehicle headlight device which can improve overlooking of pedestrians by a drive, even under adverse conditions such as nighttime or rain at night. A vehicle headlight device includes: a photoirradiator which irradiates light on a light distribution region outside of a travel roadway in an irradiation pattern in which a bright region and a dark region are alternately repeated; a detector which detects presence of a pedestrian in the light distribution region; and a controller which controls the photoirradiator based on a detection result of the detector. In this embodiment, the detector generates a detection output in which a pedestrian accuracy which is an extent to which a detection target is likely a pedestrian is a second pedestrian accuracy lower than a first pedestrian accuracy which is a degree activating a pedestrian protection brake, and the controller illuminates the photoirradiator in response to the detection output.

This application is based on and claims the benefit of priority from Japanese Patent Application No. 2022-018658, filed on 9 Feb. 2022, the content of which is incorporated herein by reference.

### BACKGROUND OF THE INVENTION

### Field of the Invention

The present invention relates to a vehicle headlight device.

### Related Art

As a vehicle headlight device, a device has been proposed whereby the driver can favorably visually recognize pedestrians, while suppressing dazing of pedestrians (for example, refer to Patent Document 1). The vehicle headlight device of Patent Document 1 configures so as to lower the amount of illumination on the upper body of a pedestrian, according to the distance until the pedestrian acquired from a pedestrian detection sensor.

Patent Document 1: Japanese Unexamined Patent Application, Publication No. 2013-184614

### SUMMARY OF THE INVENTION

However, there is a tendency of more accidents due to overlooking of pedestrians ahead of a vehicle in a straight uninterrupted road. Although it should be made so that such overlooking of pedestrians does not occur, there is no sufficient means in existing vehicle headlight devices under adverse conditions such as nighttime and rain at night in particular.

The present invention has been made taking account of the above such situation, and has an object of providing a vehicle headlight device which can improve overlooking of pedestrians by a driver, even under adverse conditions such as nighttime and rain at night.

A vehicle headlight device according to a first aspect of the present invention (for example, the vehicle headlight device 1 described later) includes: a photoirradiator (for example, the left-side pattern irradiation lamp 41 described later) which irradiates light on a light distribution region (for example, the irradiation pattern light distribution region 16 described later) outside of a travel roadway in an irradiation pattern (for example, the irradiation pattern Lp described later) in which a bright region (for example, the bright region a1 described later) and a dark region (for example, the dark region a2 described later) are alternately repeated; a detector (for example, the detector 90 described later) which detects presence of a pedestrian (for example, the pedestrian 15 described later) in the light distribution region; and a controller (for example, the lamp control ECU 40 described later) which controls the photoirradiator based on a detection result of the detector.

According to a second aspect of the present invention, in the vehicle headlight device as described in the first aspect, the detector generates a detection output (for example, the person identification signal SPi1, SPi2 as the detection output described later) in which a pedestrian accuracy which is an extent to which a detection target is likely a pedestrian is discriminated into a first pedestrian accuracy which is a degree activating a pedestrian protection brake, and a second pedestrian accuracy which is lower than the first pedestrian accuracy, and the controller illuminates the photoirradiator in a case of the detection output corresponding to the second pedestrian accuracy.

According to a third aspect of the present invention, in the vehicle headlight device as described in the first or second aspect, the controller establishes the photoirradiator as unlit in a case of the detector not detecting presence of a pedestrian in the light irradiation region, and establishes the photoirradiator as illuminated in a case of the detector detecting presence of a pedestrian in the light distribution region.

With the vehicle headlight device according to the first aspect, the controller controls the photoirradiator based on the presence/absence of the presence of a pedestrian according to the detector, and irradiates light on the light distribution region outside of the travel roadway in an irradiation pattern in which a bright region and dark region are alternately repeated. For this reason, the driver notices at an early stage there being a possibility of the pedestrian being present, and can take preparation for pedestrian discovery. Therefore, overlooking of pedestrians by the driver can be improved even under adverse conditions such as nighttime or rain at night.

With the vehicle headlight device according to the second aspect, the detector generates a detection output in which a pedestrian accuracy which is an extent to which a detection target is likely a pedestrian is a second pedestrian accuracy lower than a first pedestrian accuracy which is a degree activating a pedestrian protection brake, and the controller illuminates the photoirradiator in response to this detection output. For this reason, the driver can take preparation for pedestrian discovery at an early stage with the illumination of the photoirradiator as a trigger, whereby the speed-reduction effect by the pedestrian protection brake also improves.

With the vehicle headlight device according to the third aspect, the controller establishes the photoirradiator as unlit in the case of the detector not detecting the presence of a pedestrian in the light distribution region, and illuminates when detecting the presence of the pedestrian; therefore, the driver can take preparation for pedestrian discovery at an early stage, with the illumination of the photoirradiator as the trigger.

### BRIEF DESCRIPTION OF THE DRAWINGS

FIG. 1 is a schematic diagram showing a vehicle headlight device and detector as an embodiment of the present invention;

FIG. 2 is a conceptual block diagram showing a pattern irradiation lamp, detector and controller of the vehicle headlight device in FIG. 1;

FIG. 3 is a timing chart showing operation of the pattern irradiation lamp, detector and controller in FIG. 2;

FIG. 4 is a schematic diagram showing an irradiation pattern light distribution region of the pattern irradiation lamp in FIG. 2;

FIG. 5 is a view comparatively showing behavior of a vehicle managed by the controller in FIG. 2 with behavior of a vehicle in the case of this management not being done;

FIG. 6 is a view schematically showing the visual property of a person according to the technical concept of the present invention;

FIG. 7 is a view schematically showing a shading mask applied to the pattern irradiation lamp in FIG. 2;

FIG. 8 is a schematic diagram showing an aspect of viewing, in the driving field of view at nighttime, the irradiation light of the irradiation pattern according to the shading mask of FIG. 5;

FIG. 9 is a view, in the viewpoint of the driver, an aspect of a pedestrian standing still being irradiated by irradiation light from the pattern irradiation lamp of FIG. 2; and

FIG. 10 is a view, in the viewpoint of the driver, an aspect of a pedestrian during movement being irradiated by irradiation light from the pattern irradiation lamp of FIG. 2.

### DETAILED DESCRIPTION OF THE INVENTION

Hereinafter, an embodiment of the present invention will be explained while referencing the drawings. It should be noted that, in the following explanation, irradiation pattern light distribution region is an irradiation area of a certain specified light, and irradiation pattern is an irradiation shape of light relative to the irradiation pattern light distribution region.

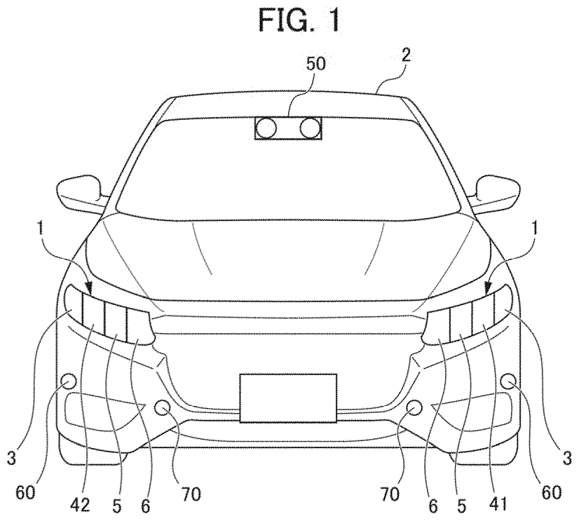

FIG. 1 is a conceptual block diagram showing a vehicle headlight device and detector of an embodiment of the present invention. The vehicle headlight devices 1 are included at each of a left side and right side in a left/right symmetrical form viewing from the central position in the vehicle width direction of a vehicle 2. In the vehicle headlight device 1, a turn signal lamp 3, pattern irradiation lamp 4, low beam lamp 5 and high beam lamp 6 are arranged in order from an outer side toward an inner side in the vehicle width direction. It should be noted that the pattern irradiation lamp 4 is a generic term for the left-side pattern irradiation lamp 41 which is a left-side photoirradiator, and a right-side pattern irradiation lamp 42 which is a right-side photoirradiator.

The detector is configured to include a camera 50, radars 60, finders 70 and an object recognizer 80 described later. The camera 50 is arranged at the upper center of a front window of the vehicle 2. The radars 60 are respectively arranged at the left side part and right side part below left/right vehicle headlight devices 1. The finders 70 are respectively arranged to be separated to left and right at positions more to the inner side than the radars 60 on the left/right at the front lower part of the vehicle 2.

The turn signal lamp 3 is a normal lamp of this type. The pattern irradiation lamp 4 as a pattern photoirradiator irradiates light onto irradiation pattern light distribution regions 16, 17 of the vehicle 2 in irradiation patterns in which a bright region and dark region are alternately repeated. The low beam lamp 5 irradiates light in a predetermined light distribution area of a low beam. The high beam lamp 6 irradiates light in a predetermined light distribution area of a high beam. It should be noted that the vehicle 2 equipped with the vehicle headlight device 1 is called one's own vehicle 2 as appropriate hereinafter. In the above, the irradiation pattern light distribution region 16 is a light distribution region on the left side which is leftwards of the travel roadway of one's own vehicle 2. The irradiation pattern light distribution region 17 is a light distribution region on the right side which is rightwards of the travel roadway of one's own vehicle 2.

The camera 50 is a stereo camera, and cyclically and repeatedly photographs ahead of one's own vehicle 2. The radar 60, for example, detects a detection target by the FM-CW (Frequency Modulated Continuous Wave) method. The finder 70, for example, is LIDAR (Light Detection and Ranging, or Laser Imaging Detection and Ranging) which measures the scattered light relative to the irradiation light, and measures the distance to a target. It should be noted that the vehicle 2 is equipped with an ADAS (Advanced Driver Assistance System) including a CMBS (Collision Mitigation Brake System).

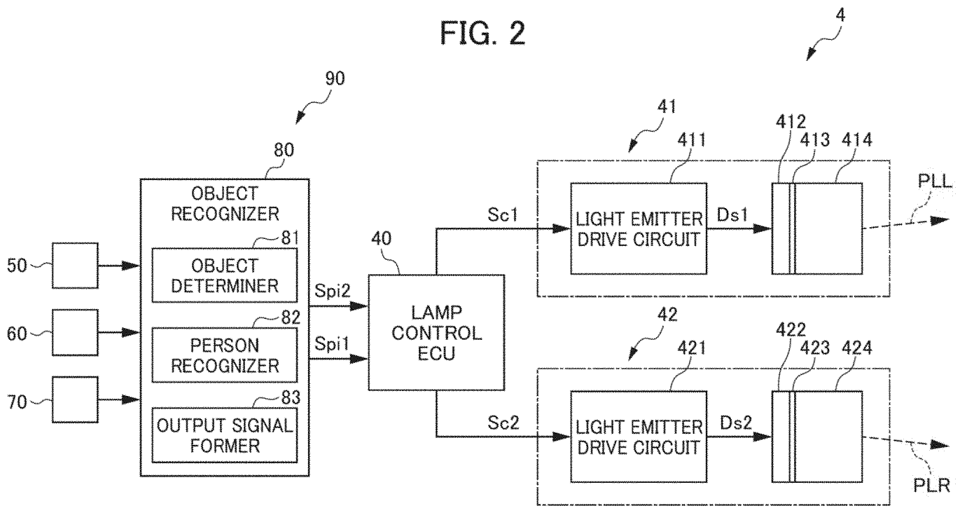

FIG. 2 is a conceptual block diagram showing a pattern irradiation lamp, detector and controller of the vehicle headlight device in FIG. 1. The detector 90 is configured to include the camera 50, radar 60, finder 70 and an object recognizer 80. The object recognizer 80 recognizes the position, type, speed, etc. of a detection target, based on the detection results from a part or all of the camera 50, radar 60 and finder 70.

The object recognizer 80 is configured to include an object determiner 81, a person identifier 82, and output signal former 83. The object determiner 81 detects the distance and direction of a detection target present within a predetermined range from one's own vehicle 2, based on distance information included in monitoring information inputted from the camera 50, radar 60 and finder 70. The object determiner 81 specifies a position indicated by the positional information included to be associated with distance information as a reference point, and establishes as a position at which the detection target is present with the distance and direction detected from the specified reference point.

The person identifier 82 identifies a person such as the pedestrian 15 described later, by referencing the captured image information from the camera 50, for the detection target caught by the object determiner 81. The output signal former 83 forms a person identification signal Spi as a detection output which is a high level H in the case of the detection target being recognized as a person, in response to the identification result of the person identifier 82, and supplies this to the lamp control ECU 40 serving as a controller.

In more detail, the person identification signal Spi as the detection output is a general term for a person identification signal Spi1 representing that a pedestrian accuracy, which is a degree to which the detection target is likely a pedestrian is a first pedestrian accuracy, which is an extent to operate a pedestrian protection brake; and a person identification signal Spi2 representing that the pedestrian accuracy is a second pedestrian accuracy lower than the first pedestrian accuracy. Therefore, in the case of the vehicle 2 traveling, the person identification signal Spi2 is issued at a moment earlier than when the person identification signal Spi1 is issued (turned to high level H).

The person identification signal Spi1 and person identification signal Spi2 are outputted by dividing the signal channels, for example, so that both are distinguished. It should be noted that it can assume a form superimposing so that both are distinguished on a single signal channel, without separating the signal channels. The lamp control ECU 40 supplies a startup command signal Sc1 and/or startup command signal Sc2 to the pattern irradiation lamp 4, in the case of the person identification signal Spi2 from the object recognizer 80 being the high level H.

The pattern irradiation lamp 4 has a left-side pattern irradiation lamp 41 which is a left-side photoirradiator, and a right-side pattern irradiation lamp 42 which is a right-side photoirradiator. The left-side pattern irradiation lamp 41 is configured to include a light emitter drive circuit 411, surface emitting element 412, shading mask 413 and projection optical system 414.

The right-side pattern irradiation lamp 42 is configured to include a light emitter drive circuit 421, surface emitting element 422, shading mask 423 and projection optical system 424. The shading mask 413 has a light transmission slit corresponding to the first irradiation pattern in which a bright region and dark region are alternately repeated. The shading mask 423 has a light transmission slit corresponding to the second irradiation pattern in which a bright region and dark region are alternately repeated. In one embodiment of the present invention, the first irradiation pattern and second irradiation pattern are the same irradiation pattern.

The light emitter drive circuit 411 of the left-side pattern irradiation lamp 41 generates the element drive signal Ds1 and supplies to the surface emitting element 412 in response to the startup command signal Sc1 supplied from the lamp control ECU 40. The surface emitting element 412 emits light in response to the element drive signal Ds1. By the emission of the surface emitting element 412, the left-side pattern irradiation lamp 41 irradiates the left-side irradiation light PLL of the first irradiation pattern towards the light distribution region 16 described later, through the shading mask 413 and projection optical system 414.

The light emitter drive circuit 421 of the right-side pattern irradiation lamp 42 generates the element drive signal Ds2 and supplies to the surface emitting element 422 in response to the startup command signal Sc2 supplied from the lamp control ECU 40. The surface emitting element 422 emits light in response to the element drive signal Ds2. By the emission of the surface emitting element 422, the right-side pattern irradiation lamp 42 irradiates the right-side irradiation light PLR of the second irradiation pattern towards the light distribution region 17 described later, through the shading mask 423 and projection optical system 424. It should be noted that the first irradiation pattern and second irradiation pattern are the same irradiation pattern in one embodiment of the present invention, as mentioned above.

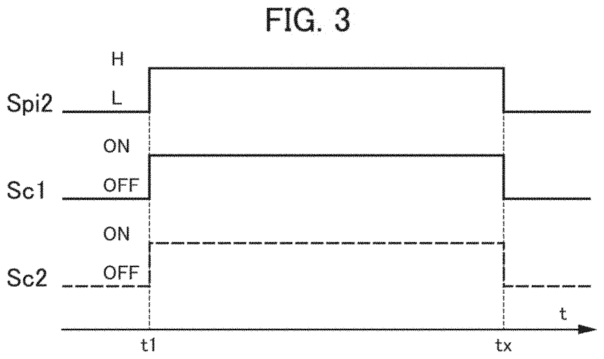

FIG. 3 is a timing chart showing operations of the pattern irradiation lamp 4, detector 90, and lamp control ECU 40 as a controller, in FIG. 2. As explained by referencing FIG. 2, the lamp control ECU 40 generates the startup command signal Sc1 to irradiate the left-side irradiation light PLL from the left-side pattern irradiation lamp 41, in the case of the aforementioned person identification signal SPi2 being the high level H, among the person identification signals Spi from the object recognizer 80 of the detector 90.

As in FIG. 3, at time t1 when the person identification signal Spi2 turns to the high level H, the lamp control ECU 40 turns ON the startup command signal Sc1 in response thereto, and the left-side irradiation light PLL is irradiated from the left-side pattern irradiation lamp 41. It should be noted that the lamp control ECU 40 generates the startup command signal Sc2 to irradiate the right-side irradiation light PLR from the right-side pattern irradiation lamp 42, when determined as being a situation without obstacles, even if irradiating the right-side irradiation light PLC, based on the information input from a higher order ECU.

In the case of the detector 90 not detecting the presence of the pedestrian 15 in the irradiation pattern light distribution region 16, the person identification signal Spi2 which establishes the photoirradiator as unlit becomes the low level L. In FIG. 3, at time tx at which the person identification signal Spi2 turns to the low level L, the lamp control ECU 40 turns the startup command signal Sc1 to the low level L in response thereto to establish the left-side pattern irradiation lamp 41 as unlit.

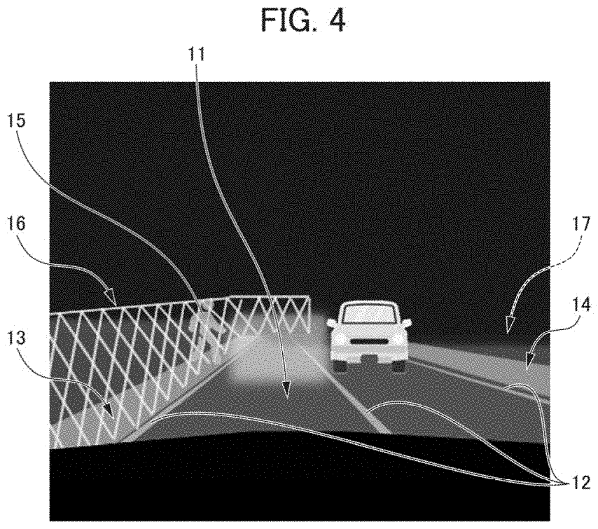

FIG. 4 is a schematic diagram showing a state viewing the irradiation pattern light distribution region of the pattern irradiation lamp of FIG. 2 in the driving field of view at nighttime. On the road 11, divider lines 12 are drawn, whereby one sidewalk 13 and another sidewalk 14 are demarcated. A case is assumed in which the pedestrian 15 is on the one sidewalk 13. A region including the one sidewalk 13 which is on the left side viewed from the driver is established as the light distribution region outside of the travel roadway. This light distribution region is the irradiation pattern light distribution region 16 irradiating the left-side irradiation light PLL of the left-side pattern irradiation lamp 41. In this case, the left-side irradiation light PLL is irradiated from the left-side pattern irradiation lamp 41, and the right-side pattern irradiation lamp 42 is left off. It should be noted that, in the case of the pedestrian 15 being in the sidewalk 14 on the other side (right side), the right-side irradiation light PLR is irradiated from the right-side pattern irradiation lamp 42, and the left-side pattern irradiation lamp 41 is left off. However, in the case of an oncoming vehicle being present in the left-side traffic, irradiating the right-side irradiation light PLR of the right-side pattern irradiation lamp 42 is inhibited. The irradiation pattern light distribution region 17 in the case of irradiating the right-side irradiation light PLR is a region as shown by the dotted arrow towards the other sidewalk 14.

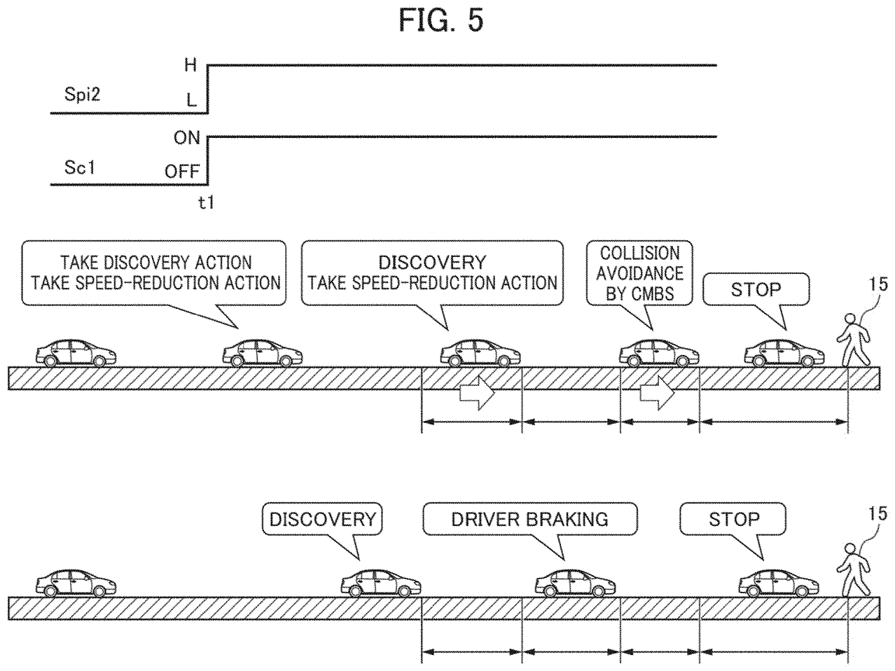

FIG. 5 is a view comparatively showing the behavior of a vehicle managed by the controller of FIG. 2 with the behavior of a vehicle in the case of this management not done. The upper part of FIG. 5 shows the behavior of a vehicle managed by the detector 90 and lamp control ECU of FIG. 2. The lower part of FIG. 5 shows the behavior of a vehicle not managed by the detector 90 and lamp control ECU of FIG. 2. The upper part of FIG. 5 shows the person identification signal Spi2 and startup command signal Sc1 similarly to FIG. 3.

At the time t1 when detecting the presence of the pedestrian 15 by the person identifier 82 of the object recognizer 80 in the detector 90, the person identification signal Spi2 supplied from the output signal former 83 to the lamp control ECU 40 turns to the high level H. The lamp control ECU 40 generates the startup command signal Sc1 to irradiate the left-side irradiation light PLL from the left-side pattern irradiation lamp 41, in response to the person identification signal Spi2 turning to the high level H. Since the left-side irradiation light PLL is irradiated from the left-side pattern irradiation lamp 41, the driver is triggered to a change in field of view, and can notice at an early stage that there is a possibility of a pedestrian 15 being present ahead, and can take a discovery action. In other words, attention is directed to the irradiation pattern light distribution region 17 ahead, and a speed-reduction action is taken. As explained by referencing FIG. 3, the condition of the person identification signal Spi2 turning to the high level H is an earlier time than the time when the person identification signal Spi1 representing that the pedestrian accuracy is the first pedestrian accuracy, which is an extent to operate a pedestrian protection brake by the CMBS is issued. For this reason, combining the effects of the speed-reduction action by the driver and pedestrian protection brake by the CMBS, a highly effective collision avoidance action is performed.

After reducing speed from the moment of time t1, the driver notices by him/herself the presence of the pedestrian 15, and takes a further speed-reduction action. In this case, as described later, since the left-side irradiation light PLL is irradiated in the irradiation pattern in which the bright region and dark region are alternately repeated in the irradiation pattern light distribution region 17, the pedestrian 15 is easily noticed. By the speed-reduction action, the vehicle speed greatly slows, and even if assuming that the timing of applying the brakes him/herself is delayed, the vehicle will stop without colliding with the pedestrian 15 by way of CMBS.

In contrast, in the case of the lower part of FIG. 5, until the driver discovers the pedestrian 15 by their own eyesight, it is not possible to notice there being a possibility of the pedestrian 15 being present ahead. For this reason, no opportunity arises to direct special attention toward the field of view ahead from the moment t1, and take the speed-reduction action, as in the example in the upper part of FIG. 5. Therefore, from the time t1, after traveling maintaining the vehicle speed for a while, the pedestrian 15 is discovered by oneself. Subsequently, the driver applies the brake, and the vehicle comes to a stop. In this case, even if CMBS is equipped to the vehicle, the burden on CMBS is great, and the brake operation by the driver also become sudden.

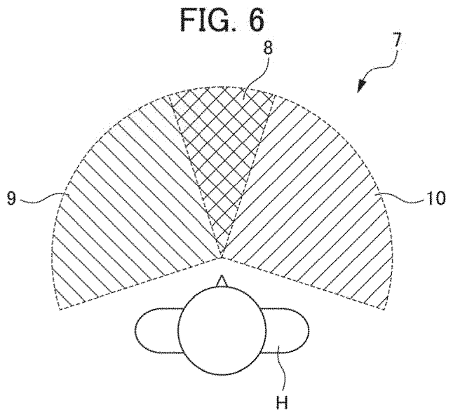

Herein, FIG. 6 is a view schematically showing a visual property of a person according to the technical concept of the vehicle headlight device 1 of the present invention described later. In FIG. 6, a forward field of view 7 of a person H is divided into a center field of view 8 which widens at a fixed acute angle to the left and right from a front face, and a left peripheral field of view 9 and right peripheral field of view 10 adjacent on the left and right of the center field of view 8, from the visual property of the person.

The general visual property of a person exhibits a tendency whereby shapes are clearly visible but reaction to movement is delayed, in the center field of view 8. The left peripheral field of view 9 and right peripheral field of view 10 exhibit a tendency whereby shapes are vague, but reaction to movement is fast, i.e. sensitivity to motion is high. The vehicle headlight device 1 of the present invention is based on the idea of actively using the aforementioned such visual property of a person.

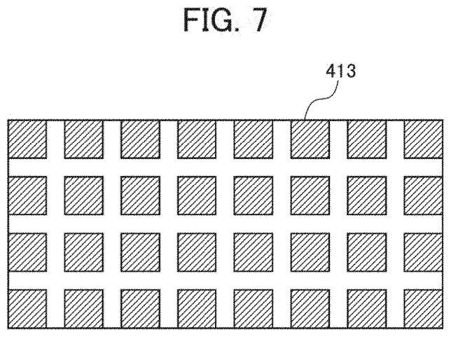

Next, by irradiating light on the irradiation pattern light distribution regions 16, 17 of the vehicle 2 in the irradiation pattern in which a bright region and dark region are alternately repeated, a phenomenon when visually confirming the pedestrian 15 from the driver will be explained by referencing FIGS. 7 to 10. It should be noted that, although the phenomenon is explained in FIGS. 7 to 10 in the case of irradiating light in the irradiation pattern in which the bright region and dark region are alternately repeated from the left-side pattern irradiation lamp 41, which is the left-side photoirradiator, this also applies to the phenomenon in the case of irradiating light by the right-side pattern irradiation lamp 42, which is the right-side photoirradiator.

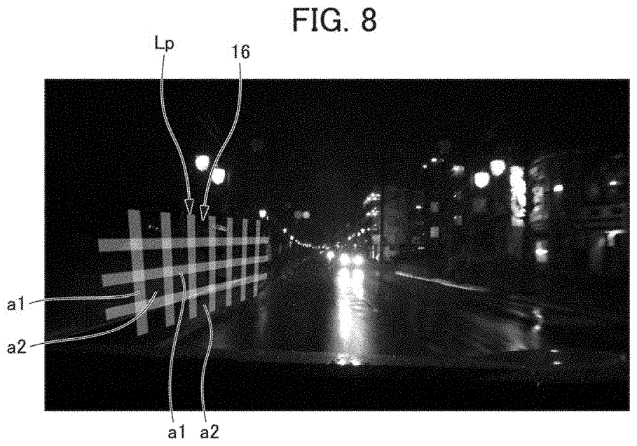

FIG. 7 is a view schematically showing a shading mask 413 applied to the left-side pattern irradiation lamp 41 of FIG. 2. FIG. 8 is a schematic diagram showing an aspect of viewing the left-side irradiation light PLL of the irradiation pattern Lp from the shading mask 413 of FIG. 7 in the driving field of view at night. The irradiation pattern Lp of the left-side irradiation light PLL of the irradiation pattern by the shading mask 413 is irradiated on the left-side irradiation pattern light distribution region 16 ahead of the vehicle 2, and is brightly visible in a grid pattern. In other words, the grid-like irradiation pattern Lp in which the bright region a1 and dark region a2 are alternately repeated can be seen.

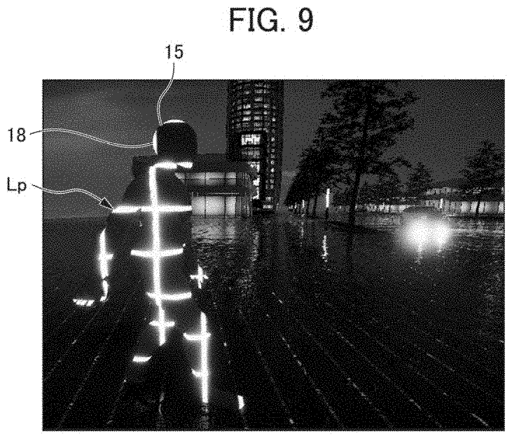

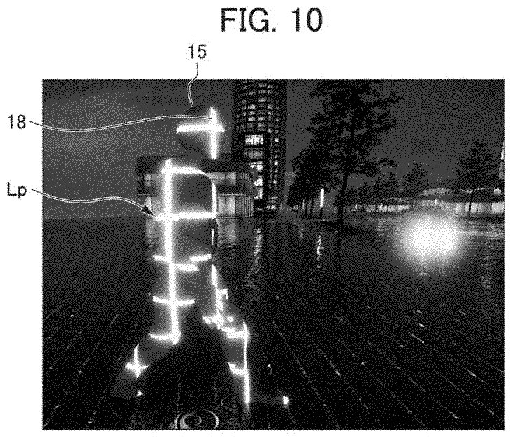

FIG. 9 is a view showing, in the viewpoint of the driver, an aspect of the pedestrian 15 standing still being irradiated by light of the irradiation pattern Lp from the left-side pattern irradiation lamp 41 of the vehicle headlight device 1. FIG. 10 is a view showing, in a viewpoint of the driver, an aspect of the pedestrian 15 during movement being irradiated by light of the irradiation pattern Lp from the left-side pattern irradiation lamp 41 of the vehicle headlight device 1.

When the pedestrian 15 moves from the roadside, as understood by referencing FIGS. 9 and 10, the shape of the bright part 18 of the grid-like pattern irradiated by light of the irradiation pattern Lp on the pedestrian 15 changes. The bright part 18 has great contrast from the adjacent parts, and is clearly visible from the driver.

In practice, the shape of the bright part 18 can be seen as changing and moving due to the visual property of people. The change in shape of the bright part 18 occurs in the peripheral field of view of the driver. It is thereby possible for the driver to immediately recognize the presence of the pedestrian 15. For this reason, overlooking of pedestrians by the driver can be remarkably improved. The configurations of the left-side pattern irradiation lamp 41 and right-side pattern irradiation lamp 42 of the vehicle headlight device 1 according to the embodiment of the present invention are not limited to the embodiment. For example, the left-side pattern irradiation lamp 41 and right-side pattern irradiation lamp 42 may be configured by projectors adopting a DMD (Digital Mirror Device) including a micro mirror group irradiating light in an irradiation pattern Lp on the irradiation pattern light distribution regions 16, 17. In addition, the lamp control ECU may cause the left-side pattern irradiation lamp 41 to always be illuminated in the case of the low beam lamp 5 being ON, and may irradiate the left-side irradiation light PLL from the left-side pattern irradiation lamp 41 to flow along the travel direction of the vehicle, at the moment when the person identification signal Spi2 turns to the high level H.

According to the vehicle headlight device 1 of the present embodiment, the following effects are exerted.

(1) The vehicle headlight device 1 includes: the left-side pattern irradiation lamp 41 which irradiates light on the irradiation pattern light distribution region 16 outside of the travel roadway in the irradiation pattern Lp in which the bright region a1 and dark region a2 are alternately repeated; the detector 90 which detects the presence of the pedestrian 15 in the irradiation pattern light distribution region 16; and the lamp control ECU 40 as a controller which controls the left-side pattern irradiation lamp 41 based on the person identification signal Spi2 of the detector 90. For this reason, the driver notices at an early stage there being a possibility of the pedestrian 15 being present, and can take preparation for pedestrian discovery. Therefore, overlooking of pedestrians by the driver can be improved even under adverse conditions such as nighttime or rain at night.

(2) In the vehicle headlight device 1, the detector 90 generates a person identification signal Spi2 as a detection output in which the pedestrian accuracy which is an extent to which the detection target is likely a pedestrian is discriminated according to a first pedestrian accuracy which is a degree activating the pedestrian protection brake, and a second pedestrian accuracy which is lower than the first pedestrian accuracy, and the lamp control ECU 40 illuminates the left/side pattern irradiation lamp 41 in the case of the person identification signal Spi2 corresponding to the second pedestrian accuracy and being the high level H; therefore, the driver can take preparation for pedestrian discovery at an early stage with the illumination of the left-side pattern irradiation lamp 41 as a trigger, whereby the speed-reduction effect by the pedestrian protection brake also improves. In addition, since the light is irradiated on the irradiation pattern light distribution region 16 outside of the travel roadway in the irradiation pattern Lp, it is possible to improve overlooking of pedestrians by the driver.

(3) In the vehicle headlight device 1, the lamp control ECU 40 establishes the left-side pattern irradiation lamp 41 or the right-side pattern irradiation lamp 42 as unlit in the case of the detector 90 not detecting the presence of a pedestrian in the irradiation pattern light distribution region 16, and illuminates when detecting the presence of the pedestrian; therefore, the driver can take preparation for pedestrian discovery at an early stage, with the illumination of the photoirradiator as the trigger.

An embodiment of the present invention has been explained above. The present invention irradiates light on the light distribution region outside of the travel roadway in the irradiation pattern in which the bright region and dark region are alternately repeated when the detector detects the presence of a pedestrian; however, this is the technical concept encompassing cases of illumination of the photoirradiator, as well as activating an alarm.

### EXPLANATION OF REFERENCE NUMERALS

a1 bright region
a2 dark region
H person
Lp irradiation pattern
Spi, SPi1, Spi2 person identification signal (detection output)
1 vehicle headlight device
2 vehicle
3 turn signal lamp
4 pattern irradiation lamp
5 low beam lamp
6 high beam lamp
7 forward field of view
8 central field of view
9 left peripheral field of view
10 right peripheral field of view
11 road
12 divider line
13 sidewalk
14 sidewalk
15 pedestrian
16 irradiation pattern light distribution region
17 irradiation pattern light distribution region
18 bright part
40 lamp control ECU
41 left-side pattern irradiation lamp
42 right-side pattern irradiation lamp
50 camera
60 radar
70 finder
80 object recognizer
81 object determiner
82 person identifier
83 output signal former
90 detector

What is claimed is:

1. A vehicle headlight device comprising:
a photoirradiator which irradiates light on a light distribution region outside of a travel roadway in an irradiation pattern in which a bright region and a dark region are alternately repeated;
a detector which detects presence of a pedestrian in the light distribution region; and
a controller which controls the photoirradiator based on a detection result of the detector.

2. The vehicle headlight device according to claim 1, wherein the detector generates a detection output in which a pedestrian accuracy which is an extent to which a detection target is likely a pedestrian is discriminated into a first pedestrian accuracy which is a degree activating a pedestrian protection brake, and a second pedestrian accuracy which is lower than the first pedestrian accuracy, and the controller illuminates the photoirradiator in a case of the detection output corresponding to the second pedestrian accuracy.

3. The vehicle headlight device according to claim 1, wherein the controller establishes the photoirradiator as unlit in a case of the detector not detecting presence of a pedestrian in the light irradiation region, and establishes the photoirradiator as illuminated in a case of the detector detecting presence of a pedestrian in the light distribution region.
